(19) United States
(12) Patent Application Publication
(10) Pub. No.: US 2018/0122470 A1
(43) Pub. Date: May 3, 2018

(54) NON-VOLATILE MEMORY, SYSTEM INCLUDING THE MEMORY AND METHOD FOR CONTROLLING THE MEMORY

(71) Applicant: STMicroelectronics S.r.l., Agrate Brianza (IT)

(72) Inventors: Fabio Enrico Carlo Disegni, Spino d'adda (IT); Maurizio Francesco Perroni, Furnari (IT); Cesare Torti, Pavia (IT); Mauro Maggiolini, Usmate-Velate (IT)

(21) Appl. No.: 15/598,962

(22) Filed: May 18, 2017

(30) Foreign Application Priority Data
Oct. 28, 2016 (IT) 102016000109360

(51) Int. Cl. G11C 13/00

(52) U.S. Cl. CPC G11C 13/0069; G11C 13/0097; G11C 13/004; G11C 13/0004

(57) ABSTRACT

A non-volatile memory includes a number of bit lines, a number of source lines, and a number of memory cells of a non-volatile type. Each memory cell is coupled between a respective bit line and a respective source line. One or more discharge lines are coupled to a reference-voltage terminal. A number of controlled switches are coupled between a respective source line and a respective discharge line, which can be selectively driven for connecting the respective source line to the respective discharge line so as to form a conductive path between the respective source line and the reference-voltage terminal.

### CROSS-REFERENCE TO RELATED APPLICATIONS

This application claims priority to Italian Patent Application No. 102016000109360, filed on Oct. 28, 2016, which application is hereby incorporated herein by reference.

### TECHNICAL FIELD

The present invention relates to a non-volatile memory, to a system including the non-volatile memory, and to a method for controlling the non-volatile memory.

### BACKGROUND

Known to the art are non-volatile phase-change memories (PCMs), in which, for storing information, the characteristics of materials that have the property of switching between phases having different electrical characteristics are exploited. For instance, these materials can switch between a disorderly, amorphous, phase, and an orderly, crystalline or polycrystalline, phase, and the two phases are associated to resistivities of considerably different value, and consequently to a different value of a datum stored. For instance, the elements of Group VI of the periodic table, such as tellurium (Te), selenium (Se), or antimony (Sb), which are referred to as chalcogenides or chalcogenic materials, can advantageously be used for providing memory cells including a phase-change storage element.

Phase change is obtained by locally increasing the temperature of the storage elements through resistive electrodes (generally known as heaters) set in contact with respective regions of chalcogenic material. There are likewise known memories in which the heater is made in an integrated form in the phase-change element. In a known way, as illustrated in FIG. 1, a non-volatile memory comprises an array 2 of memory cells 3 arranged in rows (word lines) WL and columns (bit lines) BL.

Each memory cell 3 is obtained, in the case of PCMs, by a phase-change storage element 3a (including the phase-change material and the heater coupled thereto) and by a selection device 3b, which are connected together in series. A column decoder and a row decoder (not illustrated) enable, on the basis of address logic signals received at input and decoding schemes, selection of the memory cells 3, and in particular of the corresponding word lines WL and bit lines BL each time addressed.

Selection devices, in particular N-channel MOS transistors 3b, are used for enabling and inhibiting, in respective operating conditions, a current flow for programming/reading the memory cells 3.

The selection devices 3b, the control terminal (gate) G of which is driven by one and the same word line WL, have a first conduction terminal D (drain) connected to the respective phase-change storage elements 3a and a second conduction terminal S (source) connected to a common source line 4. The selection devices 3b driven by one and the same word line WL also share one and the same source line 4. Turning-on and turning-off of each selection device 3b enables and disables, respectively, passage of an electric reading or programming current that flows from the bit line BL selected, through the respective memory cell 3, towards the source line 4. During programming, the electric current generates, by the Joule effect, the temperatures necessary for phase change.

During reading, the state of the chalcogenic material is detected by applying a voltage sufficiently low as not to cause a sensible heating and then by reading the value of the current that flows in the memory cell 3. Given that the current is proportional to the conductivity of the chalcogenic material, it is possible to determine in which state the material is, and hence trace back to the data stored in the memory cells.

With reference to FIG. 2, to program the memory cell 3′, the selection device 3b′ is switched on (by biasing the respective world line WL<0>). Since the word line WL<0> is shared by all the selection devices 3b arranged on the same row of the array 2, also the selection devices 3b will be in the ON state. The source line 4′, to which the second conduction terminal S of the selection device 3b′ is coupled, is biased at a reference voltage, for example, ground voltage (e.g., 0 V). A programming current i_{P} is made to flow in the bit line BL<0>, and hence through the phase-change element 3a′ (in particular, through the respective heater) and the selection device 3b, towards the source line 4′ coupled to the source terminal of the selection device 3b.

The remaining non-selected source lines 4 are typically biased at a voltage higher than the reference voltage (higher than 0 V, in this example), for example, equal to 1 V, and in any case in such a way that the respective gate-to-source voltage V_{GS} is lower than zero (so as to have low leakage currents). The present applicant has found that, both during programming and during reading, leakage currents i_{L} in any case leak from the non-selected source lines 4 to the selected source line 4′ (FIG. 2 shows, by way of example, only some of the leakage currents i_{L}). The leakage currents i_{L} add to the programming/reading currents and cause, on account of the intrinsic resistivity of the source line 4′, an undesired voltage drop on the source line 4′.

Since, typically, memory arrays 2 are of large dimensions (e.g., BL×WL=2048×512 or more), it is evident that the increase in voltage on the source line 4′ is not negligible.

There is hence felt the need to provide a non-volatile memory, a system including the non-volatile memory, and a method for controlling the non-volatile memory that will overcome the drawbacks set forth above.

### SUMMARY

Embodiments of the present invention provide a non-volatile memory, a system including the non-volatile memory, and a method for controlling the non-volatile.

According to one embodiment, a non-volatile memory comprises a plurality of bit lines, a plurality of source lines, and a plurality of memory cells of a non-volatile type. Each memory cell is coupled between a respective bit line and a respective source line. One or more discharge lines are coupled to a reference-voltage terminal. A plurality of controlled switches are coupled between a respective source line and a respective discharge line, which can be selectively driven for connecting the respective source line to the respective discharge line so as to form a conductive path between the respective source line and the reference-voltage terminal.

### BRIEF DESCRIPTION OF THE DRAWINGS

For a better understanding of the present invention, preferred embodiments thereof are now described, purely by way of non-limiting example and with reference to the attached drawings, wherein:

FIG. 1 shows a memory array including a plurality of cells provided with a respective phase-change memory element;

FIG. 2 shows the memory array of FIG. 1 during a programming operating step, illustrating the path of undesired leakage currents;

FIG. 3 shows a memory array including a plurality of cells provided with a respective phase-change memory element and a discharge line that forms an additional path for discharge to ground of undesired leakage currents, according to one aspect of the present disclosure;

FIG. 4 shows the memory array of FIG. 3 during a programming operating step, illustrating the path of the undesired leakage currents, according to one aspect of the present disclosure;

FIG. 5 represents the variation of the voltage drop on a selected source line of the array of FIGS. 3 and 4 as a function of the number of discharge lines formed in the memory array; and

FIG. 6 shows a simplified block diagram of an electronic system incorporating the memory array of FIG. 3 or FIG. 4, in one embodiment of the present disclosure.

### DETAILED DESCRIPTION OF ILLUSTRATIVE EMBODIMENTS

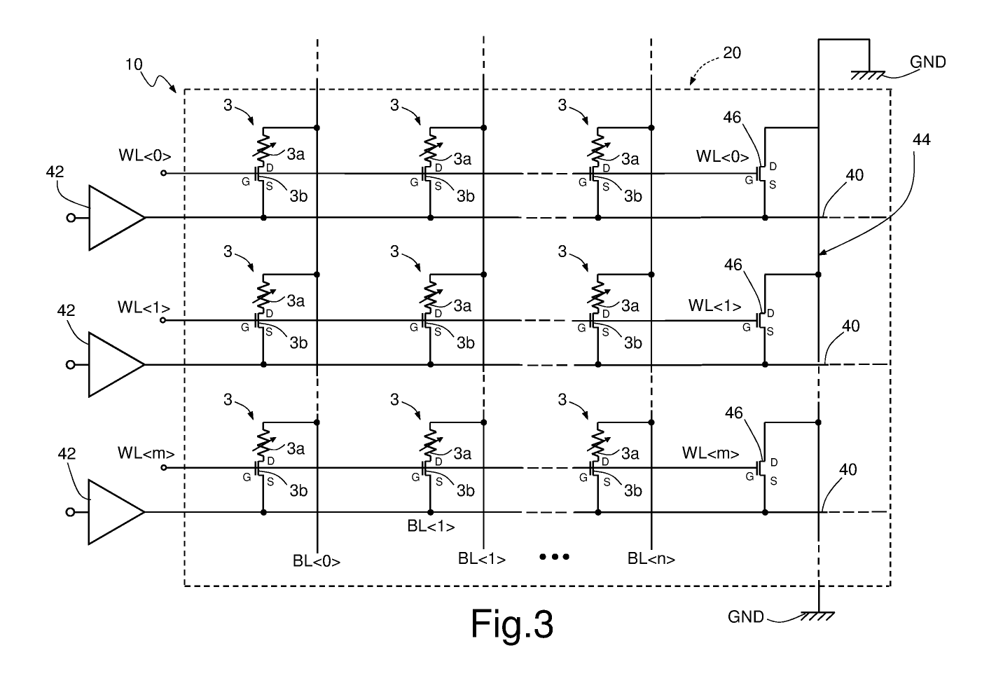

Represented schematically in FIG. 3 and designated as a whole by the reference number 10 is a portion of a non-volatile memory device, in particular of a PCM type, limitedly to just the parts necessary for an understanding of the present disclosure.

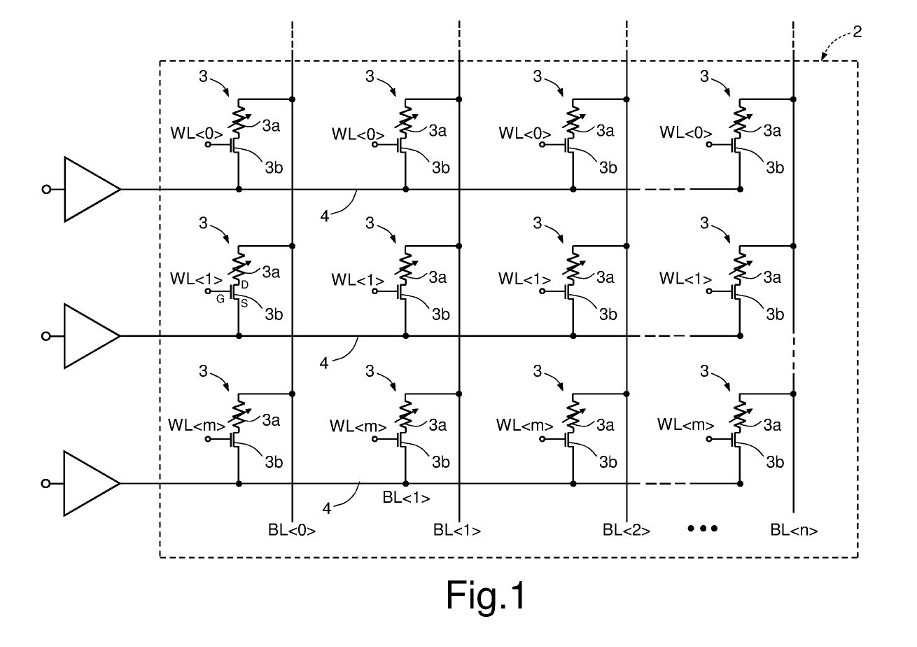

The non-volatile memory device 10 comprises a memory array 20, including a plurality of memory cells. Elements of the memory array 20 that are in common with the memory array 2 of FIG. 1 are identified by the same reference numbers and are not described in detail any further.

The memory cells 3 can hence be selected by means of word lines WL and bit lines BL. In particular, a plurality “m+1” of word lines (WL<0>, . . . , WL<m>) and a plurality “n+1” of bit lines (BL<0>, . . . , BL<n>) are represented.

The memory cells 3 comprise a phase-change element 3a and a selector element 3b, operatively coupled to the phase-change element 3a. The selector element 3b, in the embodiment illustrated, is an N-type MOS transistor having a gate terminal G connected to the respective word line WL, a first conduction terminal (drain) D connected to the phase-change element 3a, and a second conduction terminal (source) S connected to a respective source line 4, which can be biased by means of a driving element or driver 42. In particular, the driver 42 is designed to bias the respective source line 4 at a reference voltage (for example, ground, 0 V) or a voltage higher than zero (e.g., 1 V). The selector element 3b is controlled so as to enable, when selected (i.e., turned on by means of the signal of the respective local word line WL to which it is coupled), passage of a programming current (writing current, for set/reset operations) or a reading current, in the respective operating conditions, through the phase-change element 3a.

The non-volatile memory device 10 further comprises a row decoder (of a known type, here not illustrated), designed to select the word line WL corresponding to the memory cell 3 each time to be addressed, and a column decoder (of a known type and not illustrated either), designed to select the bit line of the memory cell 3 to be addressed. Given the array structure, activation of a word line WL and of a bit line BL enables unique selection of one and only one memory cell 3. A programming stage for programming the memory cells 3, which is also in itself known and is provided with a programming driver, is present but not illustrated in so far as it does not form a subject of the present disclosure.

According to one aspect of the present disclosure, the memory array 20 further includes at least one discharge line 44, which forms a column of the memory array 20 similar to the other columns of the memory array 20, but does not have any phase-change element 3a.

From the standpoint of layout, according to a non-limiting embodiment, the discharge line 44 is parallel to the bit lines BL and transverse to the source lines 4. Other layouts may in any case be envisaged.

The discharge line 44 is coupled to the reference terminal GND (e.g., to a ground potential, in particular 0 V). The discharge line 44 has a plurality of selector devices 46 similar to the selector devices 3b, for example, N-type MOS transistors. The selector devices 46 share the same word line WL as the selector devices 3b set on the same row (i.e., associated to the source line 4 itself) and, hence, have a gate terminal G connected to the respective word line WL. In particular, a first conduction terminal (drain) D of the selector devices 46 is connected to the reference terminal GND, and a second conduction terminal (source) S of the selector devices 46 is connected to a respective source line 4 (i.e., the source line 4 shared with selector devices 3b set on the same row). Selector devices 3b and selector devices 46 that share the same word line WL<0>, . . . , WL<m> share also one and the same source line 4, coupled to the respective second conduction terminal S.

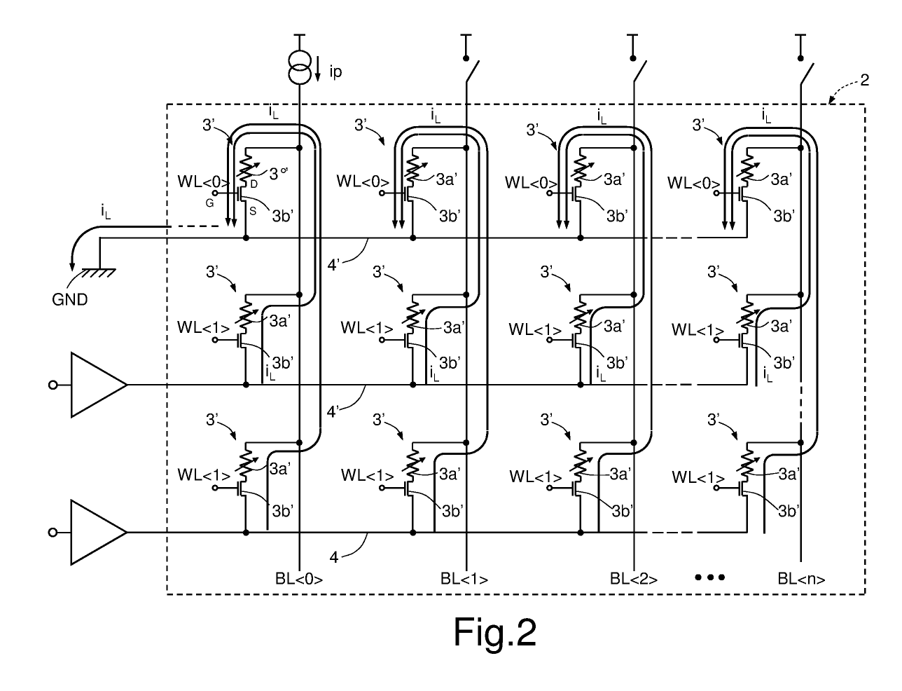

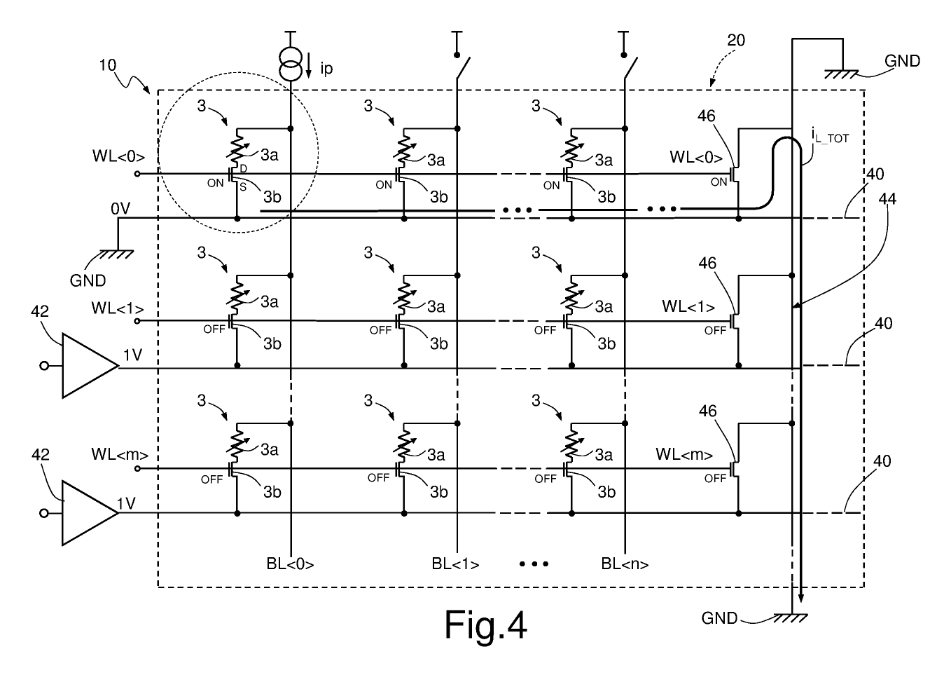

With reference to FIG. 4, in use, for example, for programming the memory cell 3, identified by a dashed circle, the word line WL<0> is biased at the ON voltage for switching on each of the transistors 3b and of the transistors 46 (in the figure, WL<0>=ON), whereas the remaining word lines WL<1>, . . . , WL<m> are biased at the OFF voltage for switching off the transistors 3b, 46 coupled thereto (in the figure, WL<1>, . . . , WL<m>=OFF). A conductive path is thus formed between the source line 4 selected and the reference terminal GND through the transistor 46 that is on (i.e., through the transistor 46 coupled to the same source line 4 as the one to which the memory cell 3 selected for programming is coupled). In this way, the leakage currents i_{L} (described with reference to FIG. 2) find a privileged discharge path to ground GND through the discharge line 44 (current flow denoted by i_{L}_{_}_{TOT}). More in particular, by providing an adequate number of discharge lines 44, the path of the current i_{L}_{_}_{TOT} on the source line 4 selected is limited in extension and, hence, the voltage drop due to the resistance of the source line 4 is not significant and does not interfere with the desired operation of the selection transistors 3b driven by the ON signal “ON” on the word line WL<0>. Consequently, the voltage on the source line 4 selected does not increase significantly.

Since the remaining transistors 46 are biased at the OFF voltages “OFF” supplied by the word lines WL<i>, . . . , WL<m>, they are inhibited (in the off state), and the respective source line 4 coupled thereto (biased at a voltage higher than 0 V, typically equal to approximately 1 V) is effectively uncoupled from the terminal at reference potential GND.

What is described with reference to FIG. 4 for programming of a logic datum in a memory cell 3 applies, in a way in itself evident to the person skilled in the art, to operations of reading of the logic datum stored in a memory cell 3.

It is evident that, to maximize discharge to ground GND of the currents present on the source line 4 selected (in particular, the leakage currents i_{L}), it may be expedient to envisage (above all in memory arrays of large dimensions) introduction of a plurality of discharge lines 44, similar to the one illustrated in FIGS. 3 and 4. For instance, it is possible to introduce a discharge line 44 every 128 bit lines BL.

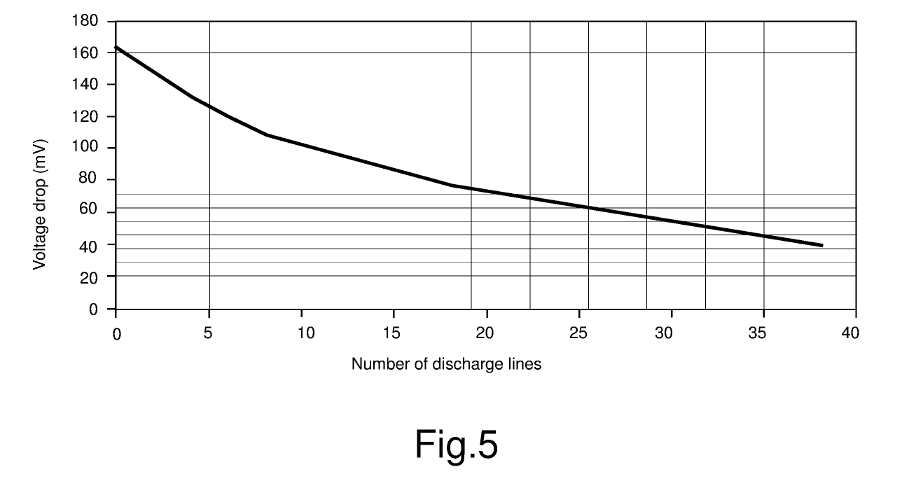

In general, the choice regarding the number of discharge lines 44 to be introduced should take into account the desired voltage drop on the source lines 4 selected. For this purpose, FIG. 5 shows a graph that illustrates the voltage drop on a source line 4 as a function of the number of discharge lines 44 introduced in the memory array 20. It is evident that the specific values illustrated in the graph of FIG. 5 regard an embodiment, and this evaluation may be made experimentally, or by means of simulation, by the person skilled in the branch, for any embodiment of the memory array (e.g., the specific numeric values may vary as a function of the materials used, of the electronic components, of the layout of the memory array, etc.).

In any case, from FIG. 5 it may be noted how, as the number of discharge lines 44 (arranged at regular intervals, for example, as has been the, every 128 bit lines BL) increases, the voltage drop on the respective source line 4 decreases, confirming the advantages of the present disclosure.

Considering a memory array 20 having 2304 local bit lines BL (columns), insertion of a discharge line 44 every 128 bit lines BL means providing a total of 18 discharge lines 44 that enable halving of the voltage drop as compared to the known art represented in FIGS. 1 and 2, with an increase in area that may be considered insignificant (lower than 1%).

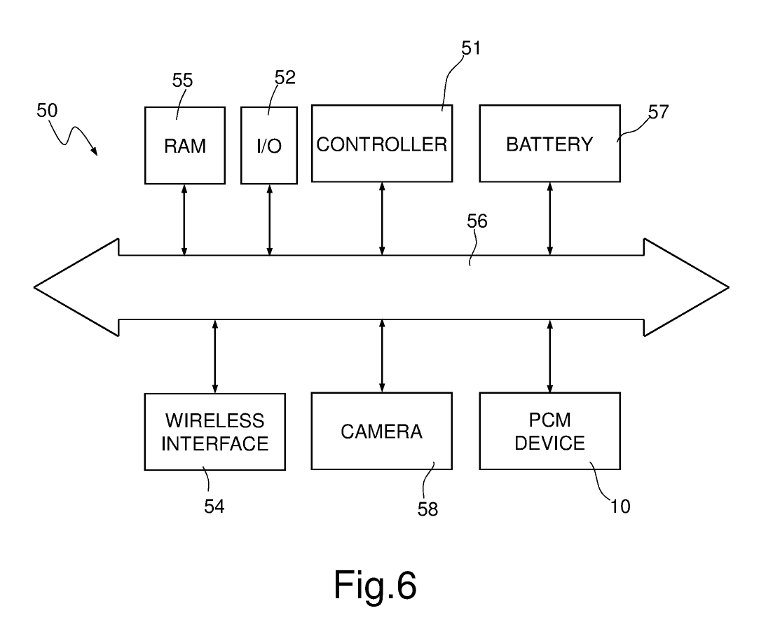

FIG. 6 illustrates a portion of an electronic system 50, according to one embodiment of the present disclosure. The electronic system 50 may be used in electronic devices, such as: a PDA (Personal Digital Assistant); a portable or fixed computer, possibly with wireless data-transfer capacity; a cellphone; a digital audio player; a photographic camera or video camera; or further devices that are able to process, store, transmit, and receive information.

In detail, the electronic system 50 comprises: a controller 51 (for example, provided with a microprocessor, a DSP, or a microcontroller); an input/output device 52 (for example, provided with a keypad and a display), for entering and displaying data; a non-volatile memory device 53, including the memory array 10 described previously; a wireless interface 54, for example, an antenna, for transmitting and receiving data through a radiofrequency wireless communication network; and a RAM 55. All these elements are coupled together through a bus 56. A battery 57 can be used as electric supply source in the electronic system 50, which may moreover be provided with a photographic camera or a video camera 58.

From what has been described and illustrated herein, the advantages that the invention according to the present disclosure affords emerge clearly.

In particular, the present disclosure enables discharge of undesired currents (leakage currents) to ground so that these currents will not flow through the source line selected throughout its extension, causing a non-negligible undesired voltage drop.

Finally, it is clear that modifications and variations may be made to what has been described and illustrated herein, without thereby departing from the sphere of protection of the present invention, as defined in the annexed claims.

For instance, what has been described previously applies, in a way in itself obvious, to other types of non-volatile memory, such as flash memories or other memories still.

What is claimed is:

1. A non-volatile memory, comprising:
a plurality of bit lines;
a plurality of source lines;
a plurality of memory cells of a non-volatile type, each memory cell being coupled between a respective bit line and a respective source line;
one or more discharge lines coupled to a reference-voltage terminal; and
a plurality of controlled switches coupled between a respective source line and a respective discharge line, selectively controllable for connecting the respective source line to the respective discharge line so as to form a conductive path between the respective source line and the reference-voltage terminal.

2. The non-volatile memory according to claim 1, further comprising a plurality of word lines, wherein the memory cells and the controlled switches coupled to one and the same source line are moreover operatively coupled to a same word line which is different from the word lines to which the other memory cells and the other controlled switches are coupled,
wherein each word line can be selectively biased to enable programming/reading of the respective memory cells and, at the same time, turning-on of the respective controlled switch.

3. The non-volatile memory according to claim 2, wherein the controlled switches are transistors having a control terminal driven in an ON state and, alternatively, in an OFF state, by a respective word line.

4. The non-volatile memory according to claim 1, wherein each memory cell includes a phase-change element provided with a resistive heater and a selector device.

5. The non-volatile memory according to claim 4, wherein the resistive heater and the selector device are connected between a respective bit line and a respective source line so that, when the selector device is in an ON state, an electric current flows between the respective bit line and source line through the resistive heater.

6. The non-volatile memory according to claim 4, wherein the selector devices are N-type MOS transistors having a drain terminal coupled to the resistive heater of the memory cell and a source terminal coupled to the source line; and
wherein the controlled switches are N-type MOS having a drain terminal coupled to the reference-voltage terminal via the discharge line, and a source terminal coupled to the source line.

7. The non-volatile memory according to claim 1, wherein the discharge lines are arranged in parallel to the bit lines, and the source lines extend in a direction transverse to the bit lines.

8. An electronic device, comprising a non-volatile memory according to claim 1, wherein the electronic device is a personal digital assistant, a portable computer, a portable phone, a smartphone, a digital audio player, a video camera, or a photo camera.

9. A method of operating the non-volatile memory according to claim 1, the method comprising:
biasing a selected source line to a first operating voltage in order to carry out a reading or programming operation in a selected one of the memory cells that is coupled to the selected source line;
supplying a current to a selected bit line that is coupled to the selected memory cell; and
selectively driving each controlled switch to connect only the selected source line selected to a discharge line so as to form a conductive path between the selected source line and a reference-voltage terminal during the reading or programming operation.

10. The method according to claim 9, method further comprising selectively biasing a selected word line coupled to the selected memory cell.

11. The method according to claim 10, further comprising connecting the selected source line to the reference-voltage terminal at the same time the selected word line is being biased.

12. A method for controlling a non-volatile memory that includes a plurality of bit lines, a plurality of source lines, a discharge line selectively coupled to the source lines, and a plurality of memory cells of a non-volatile type, each memory cell being coupled between a respective bit line and a respective source line, the method comprising:
biasing a selected source line to a first operating voltage in order to carry out a reading or programming operation in a selected one of the memory cells that is coupled to the selected source line;
supplying a current to a selected bit line that is coupled to the selected memory cell; and
coupling the selected source line to the discharge line while isolating unselected source lines from the discharge line, so as to form a conductive path between the selected source line and a reference-voltage terminal during the reading or programming operation.

13. The method according to claim 12, wherein the reference-voltage terminal is biased to the first operating voltage during the reading or programming operation.

14. The method according to claim 13, wherein the unselected source lines are biased to a second operating voltage during the reading or programming operation.

15. The method according to claim 14, wherein the first operating voltage is a ground voltage and the second operating voltage is greater than the first operating voltage.

16. The method according to claim 12, wherein the non-volatile memory further comprises a plurality of controlled switches, each controlled switch coupled between a respective source line and the discharge line, and wherein coupling the selected source line to the discharge line while isolating the unselected source lines from the discharge line comprises driving each controlled switch to connect only the selected source line selected to discharge line.

17. The method according to claim 16, wherein the non-volatile memory further comprises a plurality of word lines, wherein the memory cells and the controlled switches connected to one and the same source line are moreover operatively coupled to the same word line that is different from the word lines to which other memory cells and other controlled switches are coupled, the method further comprising selectively biasing a selected word line in order to read/program the selected memory cell and, at the same time, connecting the selected source line to the reference-voltage terminal.

18. The method according to claim 12, wherein each memory cell includes a phase-change element provided with a resistive heater and a selector device.

19. A portable electronic device comprising:
a controller;
a memory coupled to the controller;
a user interface operatively coupled to the controller;
a wireless interface operatively coupled to the controller;
a battery operatively coupled to the controller; and
a non-volatile memory operatively coupled to the controller, the non-volatile memory comprising:
a plurality of bit lines;
a plurality of source lines;
a plurality of memory cells of a non-volatile type, each memory cell being coupled between a respective bit line and a respective source line;
one or more discharge lines coupled to a reference-voltage terminal; and
a plurality of controlled switches coupled between a respective source line and a respective discharge line, selectively controllable for connecting the respective source line to the respective discharge line so as to form a conductive path between the respective source line and the reference-voltage terminal.

20. The portable electronic device according to claim 19, wherein each memory cell of the non-volatile memory includes a phase-change element provided with a resistive heater and a selector device.
